(19) United States
(12) Patent Application Publication
(10) Pub. No.: US 2005/0032350 A1
(43) Pub. Date: Feb. 10, 2005

(54) Topography controlled interconnects

(76) Inventor: Daniel Robert Shepard, North Hampton, NH (US)

Correspondence Address: Daniel R. Shepard, 186 Atlantic Avenue, North Hampton, NH, 03862, US

(21) Appl. No.: 10/912,953

(22) Filed: Aug. 6, 2004

Related U.S. Application Data
(60) Provisional application No. 60/493,111, filed on Aug. 6, 2003.

(51) Int. Cl. H01L 21/4763

(52) U.S. Cl. 438/618

(57) ABSTRACT

The present invention is a means for forming interconnect or other circuitry on a surface. The present invention utilizes a topology into which one or more layers of materials are deposited, the top layer of which is typically an etch resistant (or slow etching) material. These materials are then planarized and further processed, typically by etching. The present invention enables more conductive circuitry on the surface than would be possible with a damascene process because the present invention does not rely upon planarization to define the circuit features. Instead, the present invention uses planarization to define a pattern in a masking material that shields material beneath that masking material during subsequent processing. As a result, the material remaining after processing can extend above the topology thereby providing a greater cross section to the features and a correspondingly greater conductivity.

### CROSS-REFERENCE TO RELATED PATENT AND PATENT APPLICATION

This application makes references to U.S. Pat. No. 6,586,327 for “Fabrication of Semiconductor Devices”, issued Jul. 1, 2003 and this application claims the benefits of U.S. Provisional Application No. 60/493,111, filed on Aug. 6, 2003, and those documents in their entirety are hereby incorporated herein by reference.

### REFERENCE REGARDING FEDERAL SPONSORSHIP

Not Applicable.

### STATEMENT REGARDING FEDERALLY SPONSORED RESEARCH OR DEVELOPMENT

Not Applicable.

### FIELD OF THE INVENTION

The present invention is a method for forming circuitry on a surface, and in particular for forming circuitry on a surface of an integrated circuit using planarization and etching.

### SUMMARY OF THE INVENTION

A method for forming circuit interconnects in copper has long been performed using a technique called damascene processing. With this technique, a trench is etched into a substrate where interconnecting metal is to be placed and this trench is filled with material or layers of materials. The materials deposited are often copper preceded by a barrier layer to prevent the copper from migrating into other substrate materials. Once the materials have been deposited, the substrate is planarized back to its original surface. The result is to remove all of the deposited materials except for that deposited into the trench. In some cases, vias are additionally formed into the trenches to create contacts to circuitry in lower layers. This technique for etching both trenches and vias on a substrate into which materials are deposited and planarized to form interconnects and vias at the same time is called a dual-damascene process.

The present invention is a means for forming interconnect or other circuitry on a surface. The present invention has the advantage that the cross-sectional thickness is not limited by the depth of the trenches. This results in higher conductivity for the created features. Also, with the present invention, since the planarization does not extend all the way to the surface of the substrate, the chance of scratching that surface is greatly reduced.

### BRIEF DESCRIPTION OF THE DRAWINGS

FIG. 1. is a prior art illustration of a cross-section of a substrate having a topology following the deposition of material.

FIG. 2. is a prior art illustration of a cross-section of a substrate having a topology following planarization of the deposited material.

FIG. 3. illustrates a cross-section of a substrate having a topology following the deposition of material.

FIG. 4. illustrates a cross-section of a substrate having a topology following the planarization of the deposited material.

FIG. 5. illustrates a cross-section of a substrate having a topology following etching after the planarization of the deposited material.

### DESCRIPTION OF THE PREFERRED EMBODIMENT

The present invention utilizes a topology into which one or more layers of materials are deposited, the top layer of which is typically an etch resistant (or slow etching) material. These materials are then planarized and further processed, typically by etching. The present invention enables more conductive circuitry on the surface than would be possible with a damascene process because the present invention does not rely upon planarization to define the circuit features. Instead, the present invention uses planarization to define a pattern in a masking material that shields material beneath that masking material during subsequent processing. As a result, the material remaining after processing can extend above the topology thereby providing a greater cross section to the features and a correspondingly greater conductivity.

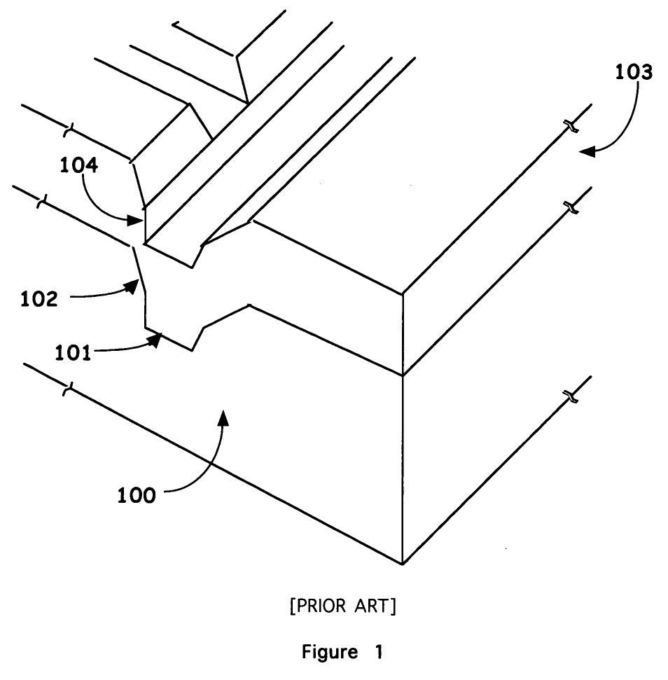

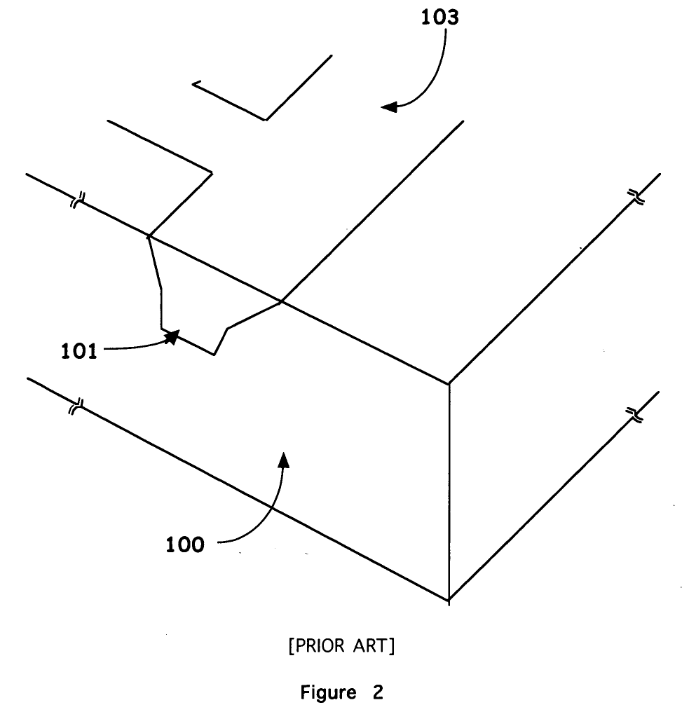

Referring to FIG. 1, the prior art a substrate (100) is prepared with a topology (101). This topology can have one or more depth features (101 and 102). Onto this topology, layers of materials (103) are deposited that fill in the topology and cover the substrate's surface. The materials generally follow the contours (104) present in the substrate's topology. This substrate is then planarized, typically using Chemical Mechanical Polishing (CMP). FIG. 2 shows the result of this CMP step; the topology (101) in substrate (100) has been filled in with layers of materials (103). Note that the conductivity of this feature is proportional to its cross-sectional area of of which its height is no more than the depth of the topology.

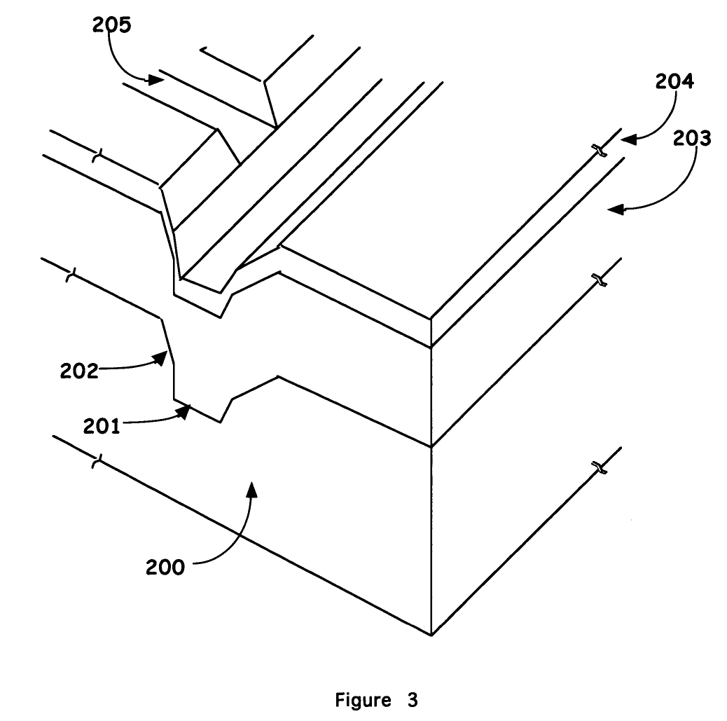

The present invention relies upon a topology based lithographic fabrication technique as described in U.S. Pat. No. 6,586,327. Referring now to FIG. 3, the present invention begins in similar fashion to the prior art damascene process. First the substrate (200) is prepared with a topology (201). This topology can have one or more depth features (201 and 202). Onto this topology, layers of materials (203) are deposited that fill in the topology and cover the substrate's surface. A top layer (204) is deposited on this stack of materials that is a material that either etches slower than the other materials or is resistant to the subsequent etch step. The materials generally follow the contours (205) present in the substrate's topology.

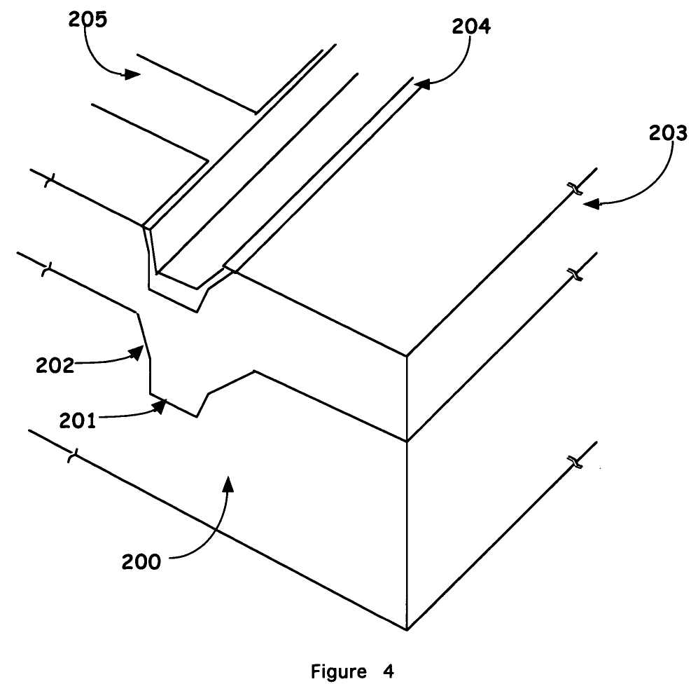

Following film deposition, the substrate is planarized. As is shown in FIG. 4, this planarization does not proceed all the way to the substrate's surface as it does with the damascene process, but rather stops at a point above the surface when the top layer material (204) remains only over those areas where it is desired to have the lower level materials (203) remaining following the subsequent etch step. The top layer material (204) will protect the layers beneath it while, at all other places, the lower level materials (203) will be exposed to the surface. In general and as is outlined in greater detail in U.S. Pat. No. 6,586,327, the topology is used to define where the etch resistant material remains after planarization.

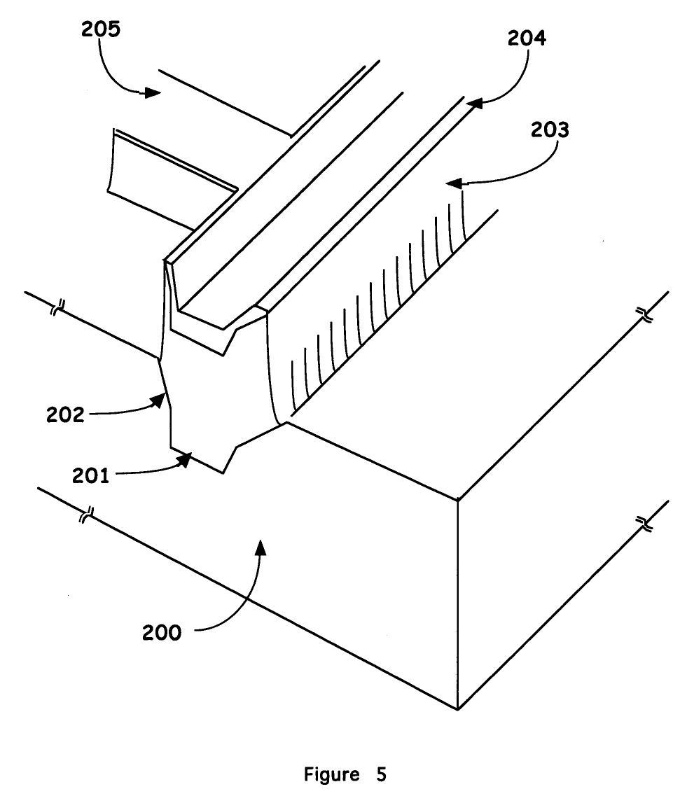

Following planarization, a reactive ion etch (RIE) or other directional etch is performed. As is shown in FIG. 5, this results in the removal of the lower level materials (203) everywhere on the substrate except where it was protected by the etch resistant material (204). Note that the stack of materials has a larger cross-sectional area because the height of the material is not limited by the depth of the topological feature, but can extend up above the surface of the substrate. This additional cross-sectional area provides a correspondingly greater conductivity to the formed circuitry.

Subsequent processing can be continued from this point. For example, a flow planarization or an oxide deposition and additional CMP planarization could be performed to passivate the surface with a new flat top surface thereby enabling the addition of additional metal conductor layers, as is commonly done today.

As mentioned above, the top material does not have to be an etch resistant material. A material that etches more slowly than the lower level materials can be used as well. This material can be deposited as a part of the film stack as described above. When the etch step is performed, the exposed lower level materials will be etched and so too will some portion of the slowly etching top level material. Also, this non-etching or slowly etching top level material could be left in place following etching or it could be removed using any of many well known processing steps. If a slowly etching material, the etch could be run until all of the top level material is removed as well.

However, a variation on the top level material deposition and planarization step can be performed. Following the deposition of the lower level material or materials, the substrate could be coated with a photosensitive polymer or other photosensitive material; this could be done using well known liquid spin deposition techniques as is done to apply photoresist today. This photosensitive material would be exposed such that the material on the surface is exposed but that material in the interior of the features of the topology is not exposed. This selective exposure can be performed in one or both of two ways. The first way would be to expose the substrate with a light source that is positioned to the side of and slightly above the substrate. This will cause shadows to be cast in the recesses and as a result not expose the photosensitive material in the recesses. The second way would be to use a photosensitive material that is sensitive only to a longer wavelength light such that that wavelength of light is too long to reach down into the small geometry features and expose the material therein. This latter approach works if the features are much smaller than the wavelength of the light used to expose that photosensitive material. In either case, and especially in the latter case, a polarized light source where the allowed polarization light is mostly perpendicular to the length of the narrow width features will improve the selectivity of the exposure. This photosensitive material is then developed in a developer solution such that the material exposed to light is rinsed away and the unexposed material remains. This photosensitive material would be selected (1) for its having an exposure wavelength that is much larger than the features that are to be left unexposed, and (2) for its slower etch rate relative to the etch rate of the lower layer of materials and such combinations of materials are well known to those skilled in the art. The substrate would then be etched (typically by RIE) and the exposed lower layer material would be etched away where they are exposed to the surface whereas the material below the now developed photosensitive material would protect the lower layer of materials, at least for a while, from that etch. Note that all of the necessary photosensitive material processing steps would be performed (such as pre-and/or post-bake).

The foregoing description of an example of the preferred embodiment of the invention and the variations thereon have been presented for the purposes of illustration and description. It is not intended to be exhaustive or to limit the invention to the precise forms disclosed. Many modifications and variations are possible in light of the above teaching. It is intended that the scope of the invention be limited not by this detailed description, but rather by any claims appended hereto.

1. A method of forming a conductive element, the method comprising the steps of:
a. defining a pattern on a substrate having a surface, the pattern comprising recesses descending below the surface of the substrate;
b. applying to the patterned substrate two or more layers each having a predetermined electrical property such as conductivity and where a layer in said series of layers is resistant to a subsequent etch step;
c. planarizing following application of at least some of the layers then disposed above the surface of the substrate; and
d. etching to define a conductive element.

2. The method of claim 1 wherein said etch resistant layer comprises chromium.

3. The method of claim 1 wherein said etch resistant layer comprises nickel.

4. A method of planarization, the method comprising the steps of:
a. defining a pattern on a substrate having a surface, the pattern comprising recesses descending below the surface of the substrate;
b. applying to the patterned substrate a layer comprising material sensitive to electromagnetic exposure;
c. electromagnetically exposing the patterned substrate at an angle such that a portion of said material residing within said recesses is shielded from said illumination; and
d. developing said material sensitive to electromagnetic exposure.

5. The method of claim 4 wherein developing said material sensitive to electromagnetic exposure results in the removal of material that has been exposed to electromagnetic illumination.

6. The method of claim 4 wherein developing said material sensitive to electromagnetic exposure results in the removal of material that has been shielded from to electromagnetic illumination.
